(19) United States
(12) Patent Application Publication
(10) Pub. No.: US 2008/0090183 A1
(43) Pub. Date: Apr. 17, 2008

(54) Aligned Carbon Nanotubes And Method For Construction Thereof

(76) Inventors: Lingbo Zhu, Atlanta, GA (US); Ching-Pong Wong, Berkeley Lake, GA (US)

Correspondence Address: TROUTMAN SANDERS LLP, 600 PEACHTREE STREET , NE, ATLANTA, GA, 30308, US

(21) Appl. No.: 11/577,621

(22) PCT Filed: Oct. 22, 2005
(86) PCT No.: PCT/US05/37694

§ 371 Date: Apr. 20, 2007

Related U.S. Application Data
(60) Provisional application No. 60/621,234, filed on Oct. 22, 2004.
(60) Provisional application No. 60/655,400, filed on Feb. 23, 2005.

(51) Int. Cl. G03F 7/40; C01B 31/00

(52) U.S. Cl. 430/324; 423/445 B

(57) ABSTRACT

Aligned carbon nanotubes and composites for electrical interconnect and thermal interface materials are provided. In one preferred embodiment, an aligned carbon nanotube device comprises a substrate and a plurality of carbon nanotubes having a substantially vertical profile. The substantially vertical carbon nanotubes are coupled to the substrate. In another preferred embodiment, a carbon nanotube production method comprises depositing a catalyst on a substrate and flowing at least one of argon, hydrogen, and ethylene over the catalyst for a predetermined time at a predetermined temperature to produce a carbon nanotube. This production method enables production of high purity carbon nanotubes and also enables precise placement of carbon nanotubes on a substrate. Other embodiments are also claimed and described.

### CROSS-REFERENCE TO RELATED APPLICATIONS

This application claims the benefit of U.S. Provisional Patent Application No. 60/621,234, filed 22 Oct. 2004, and U.S. Provisional Patent Application No. 60/655,400, filed 23 Feb. 2005, each of which are incorporated herein by reference as is fully set forth below.

### TECHNICAL FIELD

The present invention relates generally to carbon nanotubes (CNTs), and more particularly, to aligned carbon nanotubes (ACNTs) and methods for constructing ACNTs, which can be utilized in electrical interconnects, thermal interface materials, and nanoscale devices.

### BACKGROUND

Carbon nanotubes display a well-defined quasi one dimensional cylindrical structure, formed by rolling up graphene sheets of bonded carbon atoms. CNTs can be either metallic or semiconducting, depending on how the graphite layer is wrapped into a cylinder. Metallic CNTs show ballistic conductivity at room temperature. The ballistic conductivity, high thermal conductivity and mechanical strength of CNTs make them ideal candidates for electrical interconnects in IC packaging and nanoscale devices.

As integrated circuit (IC) performance increases, many technical challenges appear in the areas of power delivery, thermal management, input/output (I/O) density, and thermal-mechanical reliability. Indeed, innovative material and process solutions are crucial to sustain the microelectronic industry growth. CNTs have been investigated to address these problems, and the potential of carbon nanotubes as interconnect materials has been recognized.

Conventional CNTs and associated production methods have several drawbacks, however. For example, conventional manufacturing methods lack the ability to control both the growth of CNTs in predefined orientations and configurations and the interface with other materials such as metal electrodes. Additionally, conventional CNT production methods lack the ability to form high-aspect-ratio CNT arrays on a substrate with uniform height and diameter dimensions. Known CNT production methods further lack the ability to produce structurally perfect nanotube growth, produce defect-free nanotubes at macroscopic lengths, and control nanotube growth at specific locations on a substrate or within a device.

Conventional CNTs also have electrical property drawbacks preventing large scale adoption in interconnect applications. The electronic properties of perfect multi-walled carbon nanotubes (MWCNTs) are similar to those of single-walled carbon nanotubes (SWCNTs), due to weak coupling between the graphite cylinders. Electrons transport ballistically (without scattering) in metallic SWCNTs and MWCNTs over reasonable lengths (approximately 1 μm), thereby enabling CNTs to carry very high currents (>10⁹ A/cm2) without electromigration failure. Phonons also propagate easily along nanotubes. The measured thermal conductivity of an individual MWCNT at room temperature is >3000 W/m K, which exceeds the conductivity of diamond (2000 W/m K).

Based on these advantageous properties, CNTs would be very useful in interconnect applications. The resistance of a single ballistic SWCNT less than 1 μm long, however, is about 6.5 kΩ with perfect contacts, while ballistic transport in MWCNTs with a resistance of 12.9 kΩ. This high resistance of an individual CNT indicates that an array of many parallel CNTs is necessary for interconnect applications. Conventional manufacturing and growth processes lack the ability to produce such high density CNT arrays with high-aspect-ratio nanotubes.

Accordingly, there is a need for ACNTs and methods for construction thereof that solve these and other problems. It is to the provision of such ACNTs and ACNTs fabrication methods that the embodiments of present invention are primarily directed.

### BRIEF SUMMARY

The superior electrical, thermal, and mechanical properties of CNTs promise to bring revolutionary improvement in reducing the interconnect pitch size, increasing thermal conductivity, and enhancing system reliability. Carbon nanotubes are the fascinating one-dimensional molecular structures that can be either metallic or semiconducting, depending on their diameter and helicity. The embodiments of the present invention provide improved CNTs and CNT fabrication methods to solve the above-discussed problems.

The remarkable properties of CNTs make them attractive for microelectronic applications, especially for interconnects and nano-scale devices. Some embodiments of the present invention provide a microelectronics compatible process for growing high-aspect-ratio ACNT arrays and CNT films to produce vertical electrical interconnects. Chemical vapor deposition (CVD) can be used to fabricate highly ACNT arrays by introducing ethylene as a carbon source, and argon and hydrogen as carrier gases to an ACNT growth environment according to an embodiment of the present invention. For electronic device applications, CVD methods are particularly attractive due to the characteristic CNT growth features, such as selectivity growth of CNTs where they are required, large area deposition capability, and aligned CNT growth. The CNTs produced in accordance with the various embodiments of the present invention have high purity, and form densely-aligned arrays with controllable array size and height.

To overcome a high CNT growth temperature for microelectronic applications, an embodiment of the present invention comprises a CNT array/film transfer process. The process sequence is compatible with current microelectronic device fabrication processes, which offers the possibility of integrating CNTs with electronic devices.

Broadly described, in a preferred embodiment, a highly aligned carbon nanotube device comprises a substrate and a plurality of carbon nanotube arrays having a substantially vertical profile. The carbon nanotube arrays are coupled to the substrate. The carbon nanotube arrays can have an aspect ratio in the range of about 5 to about 32, and are preferably substantially free from impurities, such as amorphous carbon particles or other attached impurities. In addition, the carbon nanotube arrays have a pitch ranging from approximately 10 nm to approximately 30 nm, and a length of less than approximately 420 micrometers. Also, the carbon nanotube arrays produced in accordance with a preferred embodiment of the present invention can have a high carbon nanotube density, such as a density that ranges from approximately 1500 μm⁻² to approximately 2500 μm⁻². Also, the carbon nanotube arrays are preferably positioned at predetermined locations on the substrate by utilizing pre-patterned catalysts.

In another generally described preferred embodiment of the present invention, a carbon nanotube array production method comprises depositing a catalyst on a substrate, and flowing at least one of argon, hydrogen, and ethylene over the catalyst for a predetermined time at a predetermined temperature to produce a carbon nanotube array. The predetermined time can be in the range of several minutes to approximately ten minutes in accordance with a preferred embodiment of the present invention. The predetermined time can also be as long as several hours. The predetermined temperature can range from approximately 600° C. to approximately 800° C. It will be understood that other times and temperatures are also possible in accordance with the various embodiments of the present invention.

Preferably, the catalyst comprises aluminum oxide and iron. Depositing the catalyst can further include patterning a photoresist layer to form a gap in the photoresist layer to expose the substrate and placing the catalyst in the gap proximate the substrate. The photoresist layer can be a temporary layer. Also, the deposited catalyst can have a thickness of approximately 2 nm to approximately 15 nm, and more than one catalyst can be deposited. The method can also comprise placing the substrate within a vacuumed chamber and pressurizing the vacuumed chamber with argon, and flowing a gas mixture over the substrate at a flow rate ranging from approximately 50 standard cubic centimeters to approximately 1000 cubic centimeters. The gas mixture can comprise argon, ethylene, and hydrogen according a preferred embodiment of the present invention.

In yet another broadly described embodiment of the present invention, a carbon nanotube array manufacturing process comprises depositing a catalyst on a substrate at a predetermined location; and growing a carbon tube array on the substrate at a predetermined temperature until a predetermined carbon tube array height is reached. The manufacturing process can also include the carbon nanotube array for a predetermined amount of time until the predetermined carbon nanotube array height is reached.

The manufacturing process can also include additional steps. For example, the manufacturing process can include depositing a catalyst at a predetermined location comprises depositing iron particles on the substrate. Also, the manufacturing process can comprise flowing a gas mixture comprising at least one of argon, ethylene, and hydrogen proximate the catalyst on the substrate. Still yet, the manufacturing process can comprise growing the carbon nanotube array until a predetermined carbon tube array aspect ration is reached.

### BRIEF DESCRIPTION OF THE DRAWINGS

FIG. 1 illustrates a process of manufacturing ACNTs according to a preferred embodiment of the present invention.

FIG. 2 illustrates a plurality of ACNTs manufactured in accordance with a preferred embodiment of the present invention.

FIG. 3 illustrates a catalyst layer comprising nanoparticles formed on the surface of a substrate in accordance with a preferred embodiment of the present invention.

FIG. 4 illustrates a close-up view of ACNTs shown in FIG. 2, which were manufactured in accordance with a preferred embodiment of the present invention.

FIG. 5 illustrates a plurality of ACNTs having a high aspect ratio in accordance with a preferred embodiment of the present invention.

FIG. 6 illustrates a close-up view of an ACNT root manufactured in accordance with a preferred embodiment of the present invention.

FIG. 7 illustrates a series of images (FIGS. 6A, 6B, 6C, & 6D) depicting growth rates of ACNTs manufactured in accordance with a preferred embodiment of the present invention.

FIG. 8 is a chart depicting the growth rate of the ACNTs pictured in FIG. 6.

FIG. 9 illustrates a high resolution transmission microscopy image of an ACNT manufactured in accordance with a preferred embodiment of the present invention.

FIG. 10 illustrates a solder applied to an ACNT array manufactured in accordance with a preferred embodiment of the present invention.

FIG. 11 illustrates an optical micrograph of an ACNT bundle fabricated in accordance with the present invention bridging two electrodes.

FIG. 12 illustrates a current-voltage curve chart (FIG. 12A) and a capacitance-voltage curve chart (FIG. 12B) of the ACNT illustrated in FIG. 11.

FIG. 13 illustrates a process of transferring a CNT array to a substrate comprising microelectronics in accordance with a preferred embodiment of the present invention.

FIG. 14 illustrates an image of a CNT film transferred onto a substrate indicating an interconnect between the CNT and a solder in accordance with a preferred embodiment of the present invention.

### DETAILED DESCRIPTION OF PREFFERED EMBODIMENTS

It should be understood at the outset that an array of carbon nanotubes comprises numerous individual nanotubes, whether the nanotubes are single-walled or have multiple walls. This patent application at times refers to nanotubes individually and collectively (as arrays, bundles, or pillars), however, such reference is not meant to be limiting. Indeed, the discussion of individual nanotubes also applies to an array of nanotubes and vice versa because the production methods and processes discussed herein can be used to create individual nanotubes which form nanotube arrays.

A preferred embodiment of the present invention provides a simple and efficient method for growing highly-aligned and densely-packed carbon nanotubes under a wide range of growth parameters. For example, at 800° C., ACNTs manufactured in accordance with one embodiment of the present invention grow at an average rate of approximately 100 μm/min. High-resolution transmission electron microscopy HRTEM) characterization illustrates that ACNTs according to the embodiments of the present invention have high purity without any contaminants, such as carbon particles and the like.

Based on a preferred ACNT manufacturing process embodiment according the present invention, ACNTs are fabricated with pre-patterned catalysts. This fabrication technique enables precise placement and location of ACNTs on a substrate. In addition, preliminary wetting results have illustrated that ACNTs according to a preferred embodiment of the present invention can be wetted by molten solder. Thus, some embodiments of the present invention can be used as interconnects, such as chip-to-module interconnects.

ACNTs manufactured according the present invention can also be utilized in other applications. For example, some embodiments of the highly-aligned CNTs according to the present invention can be used as a thermal interface material for thermal management of ultra fast devices that dissipate high heat flux. In addition, ACNTs manufactured using a chemical vapor deposition are fully compatible with microelectronics fabrication processes and can be used in various microelectronic, photonic, interconnect, and packaging applications.

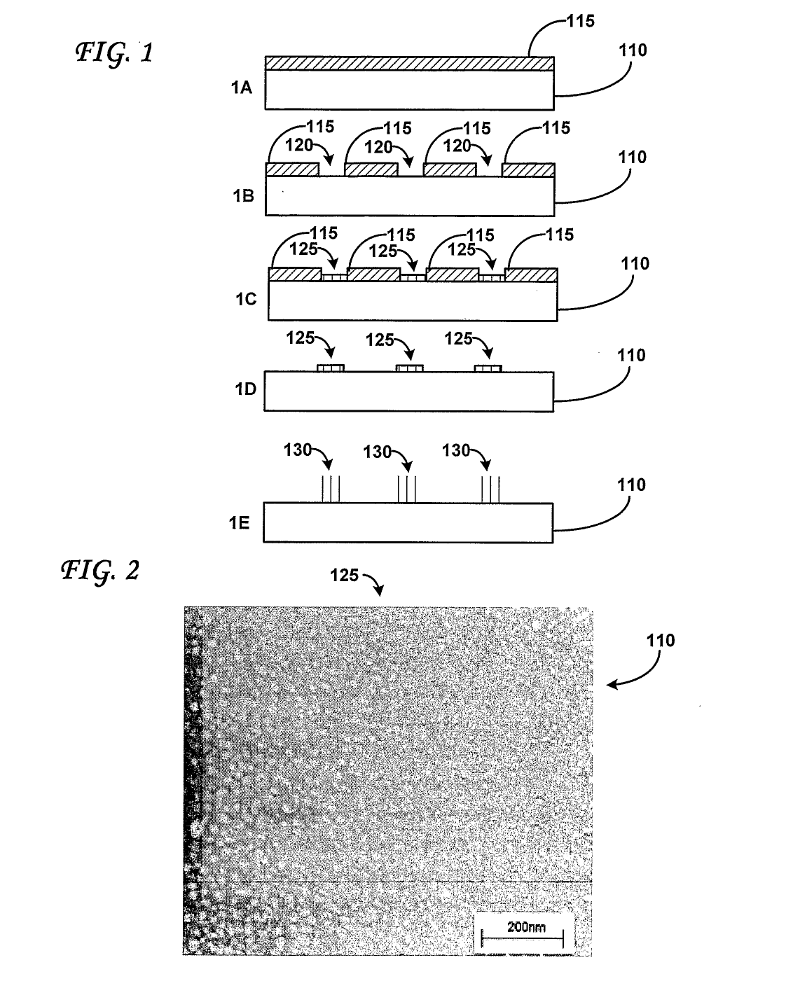

Referring now in detail to the figures, wherein like reference numerals represent like parts throughout the several views, FIG. 1 illustrates a process 100 of manufacturing ACNTs according to a preferred embodiment of the present invention. The process 100 generally includes depositing and patterning material layers upon a substrate 110. In addition, the method 100 enables ACNT catalysts to be deposited at specific locations and under control so that ACNT growth can be controlled.

The substrate is preferably a silicon wafer, but many other materials can also be utilized. In addition, a barrier layer, such as silicon oxide (not shown), having a thickness of approximately 400 nm to 500 nm can be deposited onto the substrate 110. The silicon oxide can be deposited using thermal oxidation or PECVD. The silicon oxide layer can act as a barrier between the substrate 110 and other layers to avoid intermetallization of the substrate 110 when other layers are deposited on the substrate 110. Many other materials can be used as a barrier layer in other embodiments of the present invention.

Next, and as shown in step 1A, a thin photoresist layer 115 can be deposited onto the substrate 110. The photoresist layer 115 can be Shipley 1813, and can be applied with a spin-coat technique. The photoresist layer 115 is preferably a temporary layer. Many other photoresist materials and application methods can also be utilized in accordance with the embodiments of the present invention. Once the photoresist layer 115 has been applied, portions of the photoresist layer 115 can be exposed and developed as shown in step 1B. Exposing the photoresist layer 115 to UV light can pattern the photoresist layer 115.

The exposure and development of the photoresist layer 115 creates gaps 120 between the undisturbed or remaining portions of the photoresist layer. The gaps 120 can be precisely located on the substrate 110 by exposing the photoresist layer 115. Precise location of the gaps 120 enables ACNTs to be placed at locations on a substrate 110 with great precision. The gaps 120 can have various sizes according to the present invention. For example, the gaps 120 can ranges in size from approximately 2 μm to approximately 20 μm. Larger gap 120 sizes are typically easier to fabricate than smaller gap sizes. In addition, the gaps 120 can have various geometric shapes, such as square and circular, in accordance with the various embodiments of the present invention.

In a next step, catalyst layers 125 of aluminum oxide (Al₂O₃) and iron (Fe) are deposited within the gaps 120 on the substrate 110 as shown in step 1C. The catalyst layers 125 can be approximately 0.5 nm to approximately 50 nm thick. More specifically, the aluminum oxide layer can be approximately 15 nm and the iron layer can be approximately 2 nm. In addition, many other materials such as Nickel (Ni), Cobalt (Co), and Molybdenum (Mo) can be utilized as a catalyst layer 125, and the catalyst layers can have varying thicknesses. Preferably, the catalyst layers 125 are applied using sequential electron-beam evaporation. In addition, the catalyst layer 125 can be formed on the substrate 110 using a lift-off process. Many other application methods can also be used to apply the catalyst layers 125 within the gaps 120 of the photoresist material 115.

FIG. 2 illustrates the catalyst layer 125 comprising nanoparticles formed on the surface of the substrate 110. As shown, the catalyst layer 125 comprises a plurality of iron film segregated into small particles. The image illustrated in FIG. 2 was obtained after a heat treatment and chemical vapor deposition without introducing ethylene gas or growing carbon nanotubes from the catalyst layer 125. The small iron particles have a thickness of approximately 2 nm and have diameters between approximately 5 nm and approximately 15 nm, with an average diameter of approximately 10 nm. The small iron particles also have a pitch (center-to-center spacing between adjacent particles) of approximately 15 nm. These catalyst particles form the catalyst layer 125 stimulate the growth of ACNTs in accordance to a preferred embodiment of the present invention.

ACNTs can grow from every small iron particle based particle based on the density, size, and pitch of the synthesized ACNTs. The size of catalyst particles can define the diameter of ACNTs. The inventors have also discovered that the diameter of the grown ACNTs is the same as that of the Fe islands. This discovery indicates that the small iron particle size and distribution also determine the diameter and distribution of the ACNTs manufactured in accordance with a preferred embodiment of the present invention. In addition, further reduction of the size of the iron particles (i.e., reducing the diameter and pitch of the small iron particles) will create denser ACNT arrays.

After the catalyst layers 125 have been applied to the substrate 110, the remaining portions of the photoresist layer 115 can be removed. In a preferred embodiment, the remaining portions of the photoresist layer 115 is removed by acetone. Step ID illustrates the substrate 110 without the remaining portions of the photoresist layer 115.

The substrate 110 can also be cleaned after removing the remaining portions of the photoresist layer 115 from the substrate. For example, acetone, isopropyl alcohol and distilled water can be used to clean the substrate 110. Steps 1A-D can be performed in a clean room, such as a class 1000 clean room.

In a last step of the ACNT manufacturing process 100, the substrate 110 can be placed in an environment to induce ACNT growth. According to a preferred embodiment of the present invention, the substrate 110 is placed in a tube within a furnace so that chemical vapor deposition can be utilized within the tube to grow highly-aligned CNT pillars. After being placed in the tube, pressure within the chamber is evacuated to approximately one mTorr and back-filled with argon to an atmospheric pressure (approximately 1 ATM). Then the tube can be heated to a temperature between 600° C. and 800° C. by the furnace.

When the desired temperature between 600° C. and 800° C. is reached, gases can be introduced into the tube. For example, carrier gases of argon and hydrogen can be introduced into the tube. In addition, a carbon source, such as ethylene gas, can also be introduced into the tube. The flow rates of these gases can be approximately 50 to approximately 500 standard cubic centimeters (sccm) for ethylene; approximately 50 to approximately 550 sccm for hydrogen; and approximately 100 to approximately 550 sccm for argon. Many other flow rates can also be utilized such a rates as high as 1000 sccm for each of the gases.

After a pre-determined time of the deposition, the hydrogen and ethylene flows are terminated. For example, the reaction time can be approximately 10 minutes, but the reaction time could range from less than a minute to approximately several hours. The ethylene gas is a carbon source for ACNT growth, thus is known as a precursor for ACNT growth. The hydrogen and argon gases are carrier gases, which act as dilution gases and improve the purity and quality of the ACNTs grown in accordance with the various embodiments of the present invention.

Then, the chamber can be cooled to room temperature in the presence of argon and the argon is eventually removed with the cooling is finished. Once step 1E is completed, precisely placed ACNTs have been grown and manufactured on the substrate 110 where the catalyst layers 125 were previously deposited. In addition, the ACNTs can grow from the catalyst particles illustrated in FIG. 2 such that an ACNT will grow for every catalyst particle.

In the above-described process 100 embodiment, the iron catalyst can be directly deposited on the silicon substrate by the E-beam evaporation. In some embodiments, iron particles can be deposited onto a layer of aluminum oxide. By using a photo-lithography method, it is easily to control the pattern and thickness of the iron deposition. This in turn assists in controlling the placement of and growth attributes of ACNTs when grown on the substrate 110. For example, test results for approximately ten minutes of growth at 800° C. for a sample ACNT layer using the process 100 embodiment has provided ACNTs with a diameter ranging from approximately 5 nm to approximately 20 nm, with an average diameter of approximately 10 nm. In addition, the ACNTs have a uniform height. In addition, the pitch (center to center spacing between adjacent nanotubes) has been found to be approximately 20 nm in some embodiments of the present invention. The pitch can also range from about 10 nm to about 30 nm indicating the high density of the ACNT bundles which can be grown in accordance with the present invention.

The above test results illustrate that the process 100 embodiment can produce ACNTs in large areas with different growth rates. In addition, the process 100 embodiment provides selective growth of ACNTs at locations determined by photolithography, which is compatible with current microelectronics fabrication. The patterned ACNTs with preferential growth directions can be ideal on-chip interconnect or chip to module interconnect materials.

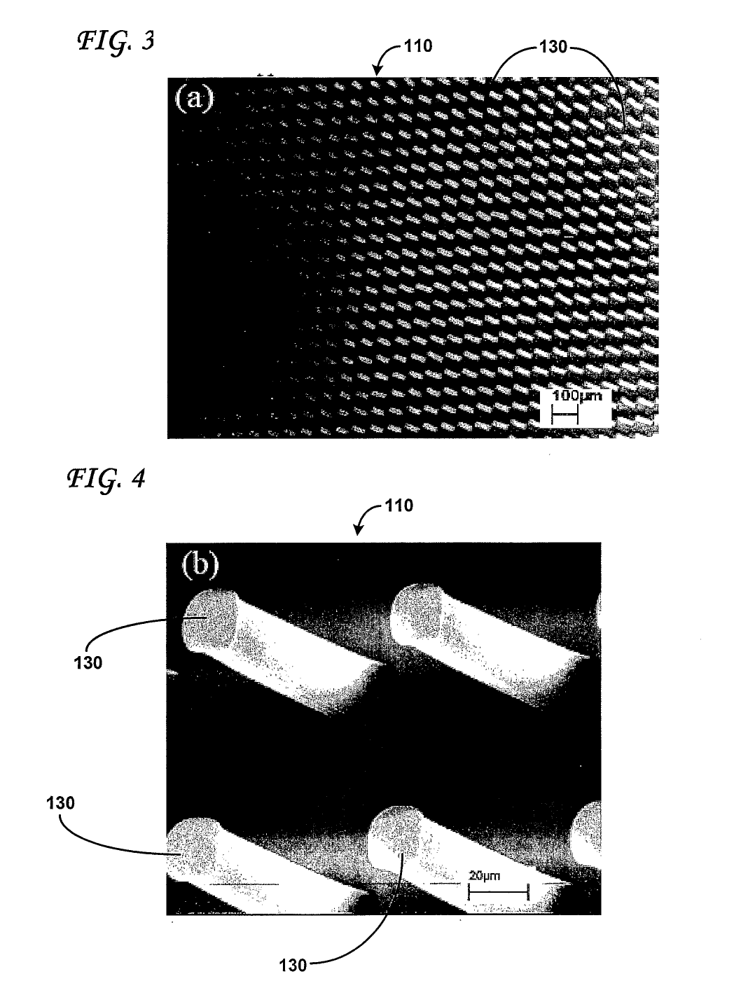

FIG. 3 illustrates a plurality (or array 300) of ACNTs 130 manufactured in accordance with a preferred embodiment of the present invention. As shown, the ACNT array 200 includes numerous ACNTs 130 grown on the substrate 110. The ACNTs shown in FIG. 3 resemble pillars and are sometimes denoted as such herein. FIG. 4 illustrates a close-up view of the ACNTs 130 illustrated in FIG. 2. Both FIGS. 3 and 4 are images from a scanning electron microscope (SEM). As FIGS. 3 and 4 illustrate, the nearly vertically ACNTs 130 can be formed on the substrate 110 without becoming entangled with a neighboring ACNT 130.

A preferred embodiment of the present invention makes possible the controlled growth of CNTs at different hierarchy levels. At the atomic level, the structure of each CNT is controlled by the reaction chemistry and growth condition. At the nano-scale, the particle size of the iron catalyst and the distance between each catalyst particles determines the density of the CNTs in each CNT bundle. Using small catalyst particle having a close distance to each other, high CNT density can be achieved. High CNT density forces the CNTs to grow vertically aligned as illustrated in FIGS. 3 and 4. At the micron-scale, ACNT bundle location is defined through a photolithography process that controls the size and pitch of the bundles according to a preferred embodiment of the present invention. Controlling ACNT growth at different particle levels enables the production of substantially vertically ACNTs and enables device manufacturers to produce the precisely-sized ACNT for a specific application.

From the microscopic to the macroscopic level, the alignment of CNTs makes possible novel interconnect structures. These structures can be produced with methods compatible with existing IC fabrication sequences. This makes it possible to fabricate ACNTs as an interconnect material using an existing IC manufacturing line.

In addition to manufacturing concerns, controlled growth of ACNTs enables device manufacturers to produced ACNT arrays having high densities. For example, the inventors estimate that manufacturing ACNT arrays in accordance with present invention can produce an ACNT array have a density of approximately 1500 μM⁻². In addition, and as discussed in detail below, examination of ACNT bundles detected no elements except carbon and revealed no particles attached to ACNT walls. These results indicate the high purity of the ACNTs. Also, most of the ACNTs grown in accordance with a preffered embodiment of the present invention can be double-walled or triple-walled having an average diameter of approximately 10 nm.

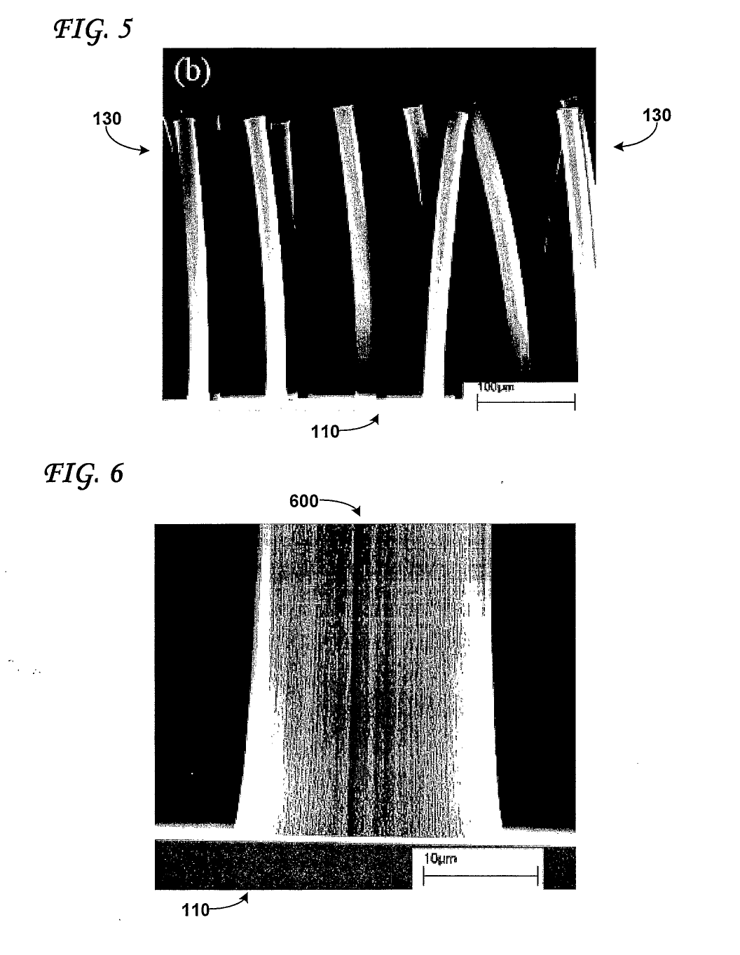

FIG. 5 illustrates a plurality of ACNTs having a high aspect ratio in accordance with a preferred embodiment of the present invention. FIG. 5 is also an SEM image of ACNTs. As shown, the CNT pillars have a high aspect ratio (approximately 15) and tend to bend a few degrees due to gravity. The inventors have discovered from experimentation that ACNT pillars can keep substantially vertically aligned with an aspect ratio up to approximately 5 with a height of approximately 150 μm. These height and aspect ratio dimensions can satisfy most interconnect applications, and thus enable some embodiments of the present invention to be utilized in such applications.

FIG. 6 illustrates a close-up view of an ACNT array 600 manufactured in accordance with a preferred embodiment of the present invention. Specifically, FIG. 6 illustrates an enlarged image of a base of a free-standing nanotube array which indicates the well-defined edges of an ACNT array fabricated in accordance with a preferred embodiment of the present invention. FIGS. 3-6 illustrate that the height and aspect ratios of ACNTs grown in accordance with the various embodiments of the present invention can satisfy most interconnect applications and requirements.

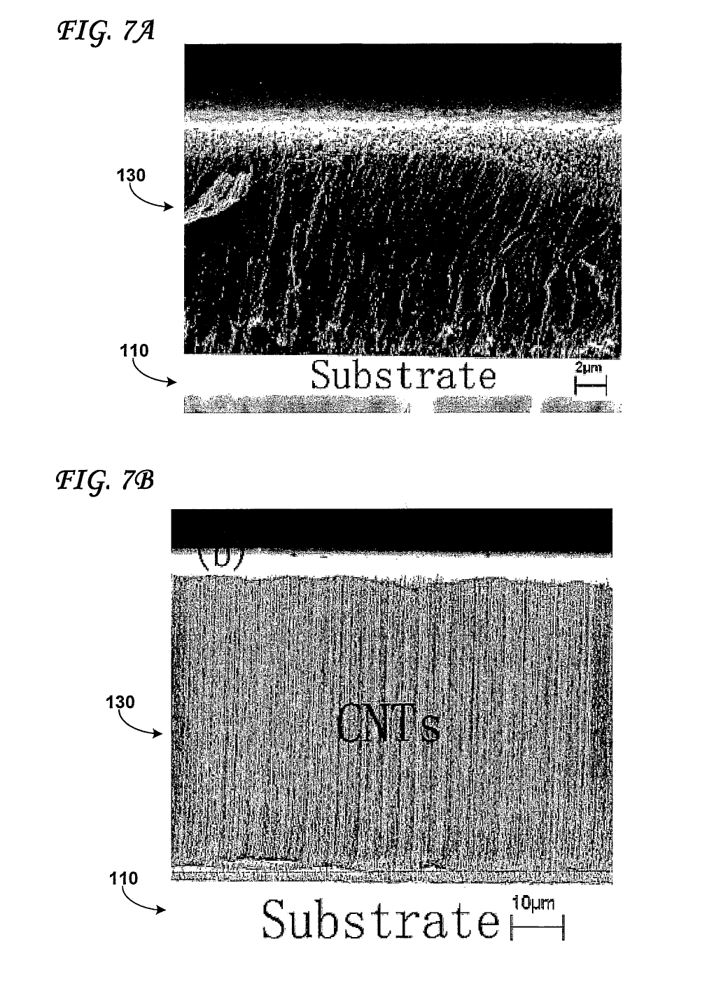

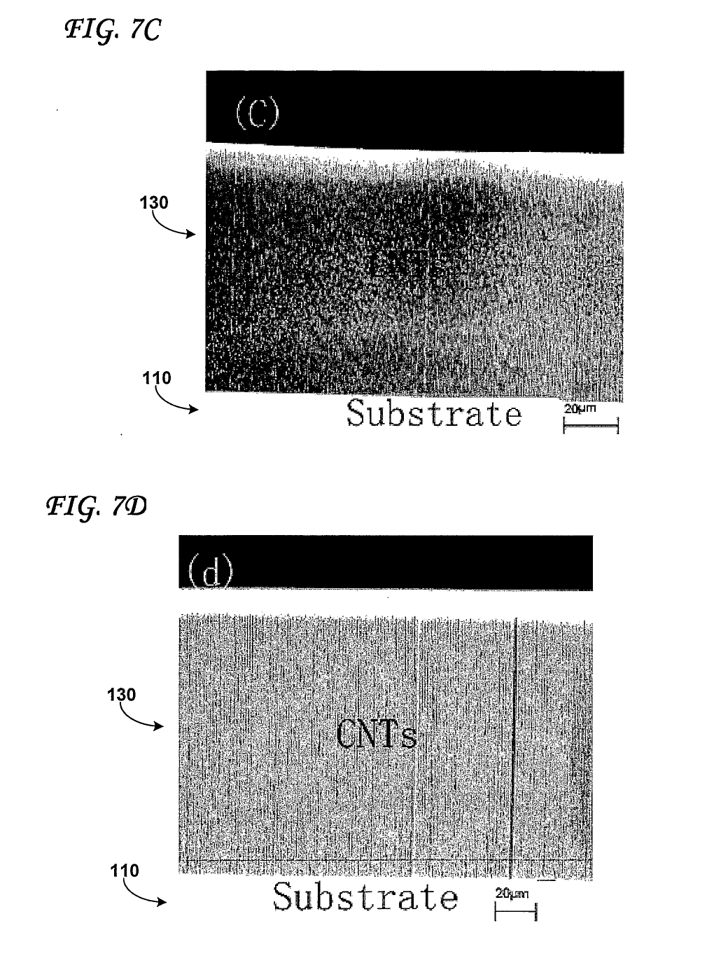

FIG. 7 illustrates a series (FIGS. 7A, 7B, 7C, & 7D) of images depicting growth rates of ACNTs manufactured in accordance with a preferred embodiment of the present invention. The inventors have discovered that the growth rate of ACNT using the process 100 embodiment process can be controlled by varying reaction temperature. With other manufacturing conditions kept constant, the inventors varied growth temperatures at the following temperatures: 650° C., 675° C., 700° C., and 750° C. FIG. 7A illustrates ACNT growth at 650° C.; FIG. 7B illustrates ACNT growth at 675° C.; FIG. 7C illustrates ACNT growth at 700° C.; and FIG. 7D illustrates ACNT growth at 750° C. The average growth rate increases from below about 6 μm/min at approximately 675° C. to about 100 μm/min at approximately 800° C.

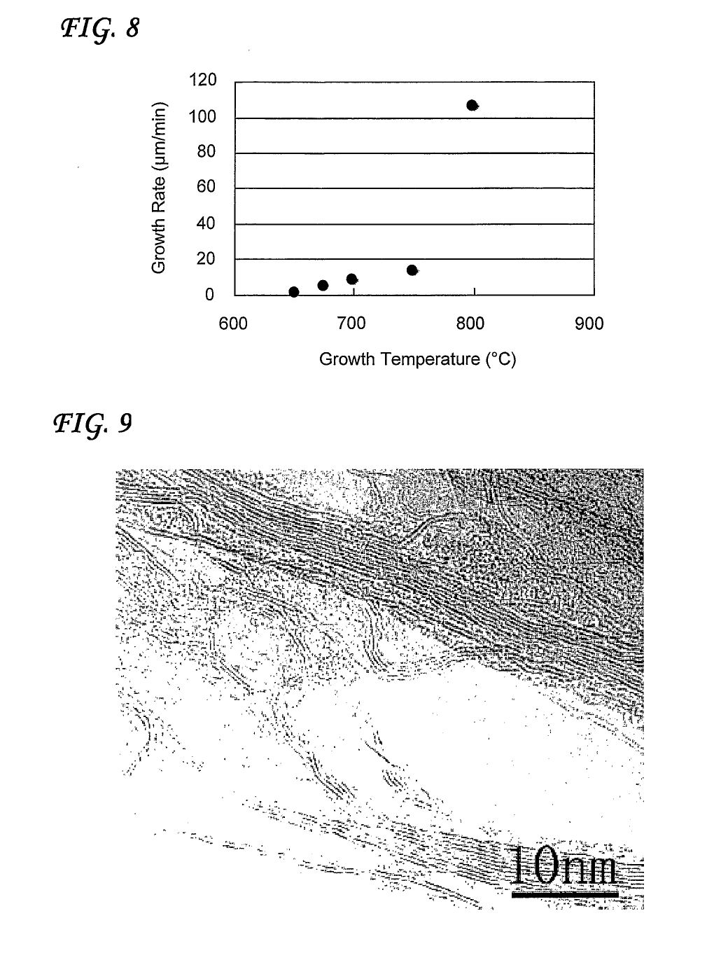

In the inventor's growth rate experiment, the reaction time in all cases was 10 minutes. The growth rate at each temperature (including 800° C. as discussed above) was calculated and listed in FIG. 8. As illustrated in FIG. 8, the growth rate for temperatures lower than 750° C. is less than 20 μm/min. Also, as shown in FIG. 8, at temperatures below 750° C., the growth rate of ACNTs increases linearly with an increasing reaction temperature. At a higher temperature of approximately 800° C., the growth rate increases dramatically, reaching approximately 100 μm/min.

FIG. 9 illustrates a high resolution transmission microscope image of an ACNT manufactured in accordance with a preferred embodiment of the present invention. As understood by those skilled in the art, chemical vapor deposition synthesis of CNTs usually introduces the formation of amorphous carbon particles or other impurities on CNTs. These impurities limit CNT applications in the microelectronic industry because the impurities are often conductive particles, which can cause shorts in the circuits or interconnects.

A preferred embodiment of the present invention overcomes this limiting drawback of known CVD processes. Indeed, the inventors discovered that the hydrogen and ethylene process 100 produces high purity CNTs. These high purity CNTs do not have any attached particles or impurities as shown in FIG. 9. FIG. 9 also illustrates that the ACNTs can be multi-walled CNTs with a diameter of approximately 10 nm.

The inventors also used a spatially resolved energy-dispersive X-ray spectroscopy (EDS) to examine ACNTs produced in accordance with a preferred embodiment of the present invention. The inventors used the EDS to examiner the purity of the ACNTs and the catalyst locations along the length of the nanotubes. The EDS detected no other elements except carbon. This finding indicates that the ACNTs produced in accordance with the ethylene and hydrogen process 100 embodiment according to the present invention have high purity. ACNT purity is determined experimentally by imaging, X-ray photoelectron spectroscopy, and energy-dispersive X-ray spectroscopy. Also, thermal gravimetric analysis (TGA) indicates that the residue is only about 2% of the original weight indicating that the ACNTs produced in accordance with a preferred embodiment of the present invention are very pure.

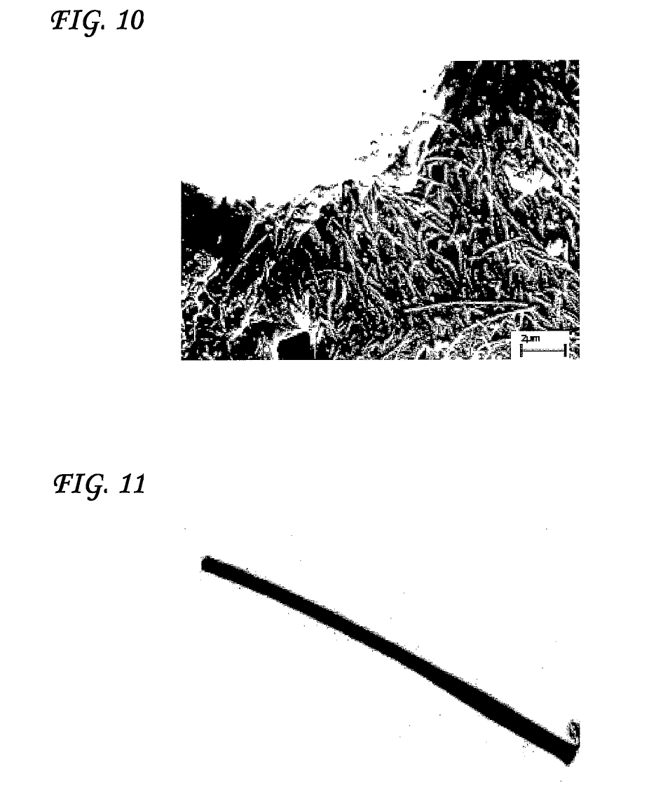

FIG. 10 illustrates a solder applied to an ACNT array manufactured in accordance with a preferred embodiment of the present invention. To investigate the feasibility of ACNT pillars as chip-to-module interconnects, the inventors studied the CNT/solder interface after a solder reflow process.

ACNT pillars were placed onto a thin layer of 63Sn/37Pb solder paste on a copper-laminated substrate. After reflow in a seven-zone BTU reflow oven under varying temperatures, the interface between CNT and solder was characterized by an SEM and is illustrated in FIG. 9. It has been reported that there is an upper surface tension limit for a liquid (˜180 mN/m) to wet the multi-walled CNTs. The surface tension of eutectic Sn/Pb at 220° C. is about 520 mN/m. The inventors discovered that ACNTs produced in accordance with a preferred embodiment were capable of being wet by as shown in the FIG. 10. The solder metals reacted with the oxygen or carbon to form a compound with sufficiently low surface tension to be drawn into the ACNT by capillary force.

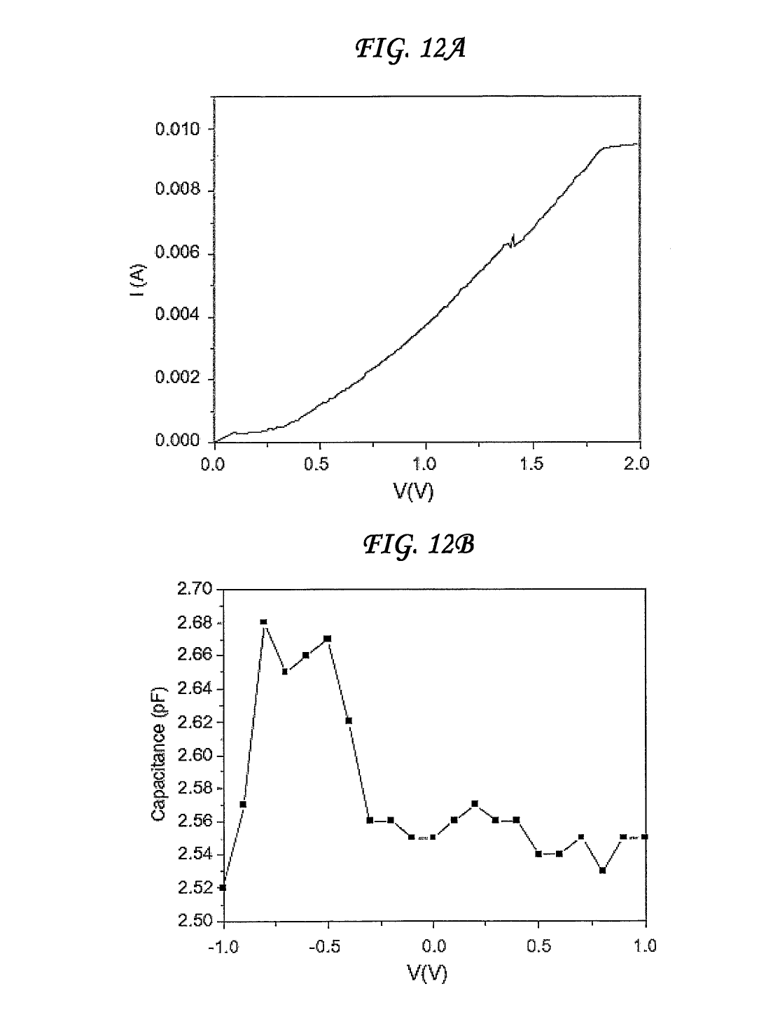

In addition to analyzing and examining the high purity states of ACNTs fabricated in accordance with the present invention, the inventors also analyzed the electrical properties of the ACNTs. FIG. 11 illustrates an optical micrograph of an ACNT bundle fabricated in accordance with the present invention bridging two electrodes, and FIG. 12 illustrates a current-voltage curve chart (FIG. 12A) and a capacitance-voltage curve chart (FIG. 12B) of the ACNT illustrated in FIG. 11.

The distance between two electrodes near the ends of the nanotube bundle is approximately 215 μm. The measured electrical resistance is approximately 250 Ω, which corresponds to a resistivity of 0.009 Ωcm. The current-voltage measurements (FIG. 12A) indicate that contact resistance exists. Also, the nearly linear relationship observed between current and voltage is good indication of metallic conductivity. Similarly, except for nanotube defects, the high measured resistance of metallic nanotubes is also due to high contact resistance caused by the unique electronic structure of nanotubes, which gives rise to weak electronic coupling at the Fermi surface. Moreover, in the inventors' tests, test probes contacted only the sidewalls of the nanotubes during current and voltage measurements. As a result, higher electrical resistance is observed, since the electrical resistance in directions vertical to the tube axis is much larger than that parallel to the tube axis.

As shown in FIG. 12B, the capacitance of the ACNT bundle of FIG. 11 was approximately 2.55 pF as the voltage was scanned from approximately −1 V to +1 V. These preliminary measurement results indicate that ACNTs and ACNT arrays manufactured and grown by a preferred embodiment of the present invention are promising for electrical interconnect applications. The inventor's test results also indicate, however, that the resistance and capacitance are still too large for direct CNT interconnect applications due to the elevated contact resistance between ACNTs and ACNT arrays, and other metal bonding pads/electrodes.

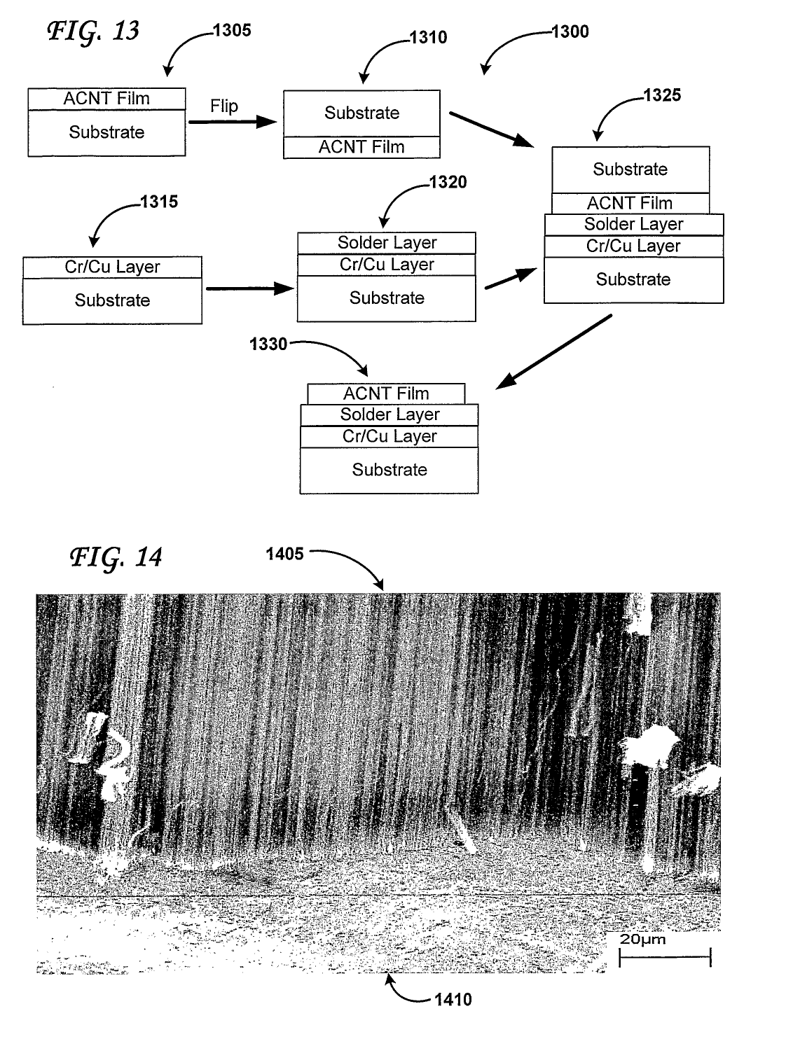

Some embodiments of the present invention also provide a process of transferring a CNT array film from on substrate to another surface. In reality, CNT growth is inevitably accompanied with high growth temperature (>600° C.). At such high temperature, however, most microelectronics devices can not survive. To overcome this drawback, the inventors have discovered a CNT pattern/film transfer process. FIG. 13 illustrates a process 1300 of transferring a CNT array to a substrate comprising microelectronics in accordance with a preferred embodiment of the present invention.

First, ACNT arrays (or film) are grown on a silicon substrate at 1305 according to the process 100 described above. While this process 1300 works with ACNTs, traditional CNTs can also be transferred using process 1300. Then, a silicon wafer having CNT films is flipped at 1310 and bonded to a second substrate with a solder to form a module at 1325. As shown at 1315, 1320, the second substrate can include a copper or chromium layer and a solder layer. The solder can be printed or electroplated onto the second substrate, which can be coated with electrodes. Then the module can be processed in a reflow oven. Finally, the top silicon wafer on which the ACNT film was grown can be removed. The end result as shown in FIG. 13 is a substrate having an ACNT film coupled to it for possible interconnect with another electronic device.

The process 1300 is suited for both closed-ended and open-ended CNTs. Preferably, the process is applied to open-ended CNT structures. The solder can be Sn/Pb, or the solder could be a lead-free solder, such as Gold/Silver (Sn/Ag), Tin/Silver/Copper (Sn/Ag/Cu), or Tin/Gold (Sn/Au). An alternative process involves depositing a solder on the CNTs to form a module, then flipping the module, and bonding the module onto a second substrates without solder using a reflow process. FIG. 14 illustrates an image of a CNT film 1405 transferred onto a substrate 1410 indicating an interconnect between the CNT film 1405 and a solder in accordance with a preferred embodiment of the present invention

While the various embodiments of this invention have been described in detail with particular reference to exemplary embodiments, those skilled in the art will understand that variations and modifications can be effected within the scope of the invention as defined in the appended claims. Accordingly, the scope of the various embodiments of the present invention should not be limited to the above discussed embodiments, and should only be defined by the following claims and all equivalents.

1-20. (canceled)

21. A method to prepare a substrate, comprising:
depositing a barrier layer onto a substrate;
depositing a photoresist layer onto a substrate;
exposing selected areas of the photoresist layer to ultraviolet light forming gaps in the photoresist layer;
depositing layers of catalyst within the gaps in the photoresist layer; and
removing the remaining layer of photoresist.

22. The method of claim 21, further comprising depositing a layer of silicon oxide approximately 400 nanometers to 500 nanometers thick onto a silicon wafer by thermal oxidation.

23. The method of claim 21, further comprising exposing areas that range in width from approximately 2 μm to approximately 20 μm.

24. The method of claim 21, further comprising depositing aluminum oxide and iron within the gaps in the photoresist layer.

25. The method of claim 24, further comprising depositing layers of catalyst ranging in thickness from approximately 0.5 nanometers to approximately 50 nanometers.

26. The method of claim 25, further comprising depositing catalyst layers such that the aluminum oxide layer is approximately 15 nanometers thick and the iron layer is approximately 2 nanometers thick.

27. The method of claim 21, further comprising applying the catalyst layers using sequential electron-beam evaporation.

28. A method to produce a device with an array of carbon nanotubes, the method comprising:
depositing a barrier layer onto a first substrate;
depositing a photoresist layer onto the first substrate;
exposing selected areas of the photoresist layer to ultraviolet light forming gaps in the photoresist layer;
depositing a catalyst within the gaps in the photoresist layer;
removing the remaining layer of photoresist; and
placing the first substrate in a furnace and utilizing chemical vapor deposition to grow carbon nanotube pillars on the catalyst layers.

29. The method of claim 28, further comprising:
evacuating the chamber of the furnace until a pressure of approximately 1 mTorr is reached; and
back filling the chamber with argon until a pressure of approximately 1 ATM is reached.

30. The method of claim 29, further comprising increasing the temperature within the chamber to a temperature between approximately 600° C. to approximately 800° C.

31. The method of claim 28, further comprising injecting carrier gases and a carbon source into the chamber of the furnace.

32. The method of claim 31, further comprising injecting ethylene at a flow rate of approximately 50 to 500 standard cubic centimeters per minute, injecting hydrogen at a flow rate of approximately 50 to approximately 550 standard cubic centimeters per minute, and injecting argon at a flow rate of approximately 100 to approximately 550 standard cubic centimeters per minute.

33. The method of claim 30, further comprising growing carbon nanotubes at a growth rate of approximately 100 μm per minute at a temperature of approximately 800° C. within the chamber of the furnace.

34. The method of claim 28, further comprising:
depositing a layer of solder onto a second substrate;
attaching the top ends of the carbon nanotubes of the array to solder of the second substrate; and
removing the first substrate.

35. A device comprising:
a substrate, and
a plurality of carbon nanotubes forming an array, each carbon nanotube disposed traverse to the substrate at a predetermined location on the substrate.

36. The device of claim 35, the carbon nanotubes having an aspect ratio in the range of approximately 8 to approximately 32.

37. The device of claim 35, the carbon nanotubes having an average pitch of approximately 10 nanometers to approximately 30 nanometers.

38. The device of claim 35, the carbon nanotubes having an average pitch of approximately 20 nanometers.

39. The device of claim 35, the array of carbon nanotubes having a density that ranges from approximately 1500 μm⁻² to approximately 2500 μm⁻².

40. The device of claim 35, the carbon nanotubes having an aspect ratio of approximately 5 with a height of approximately 150 μm.
